(19) United States
(12) Patent Application Publication
(10) Pub. No.: US 2025/0358993 A1
(43) Pub. Date: Nov. 20, 2025

(54) MULTI-GATE NEGATIVE DIFFERENTIAL IMPEDANCE DEVICE FOR SRAM

(71) Applicant: Intel Corporation, Santa Clara, CA (US)

(72) Inventors: Abhishek A. Sharma, Portland, OR (US); Anand S. Murthy, Portland, OR (US); Sagar Suthram, Portland, OR (US); Pushkar Sharad Ranade, San Jose, CA (US); Wilfred Gomes, Portland, OR (US); Tahir Ghani, Portland, OR (US)

(21) Appl. No.: 18/666,039

(22) Filed: May 16, 2024

(51) Int. Cl. H10B 10/00

(52) U.S. Cl. CPC H10B 10/12

(57) ABSTRACT

Described herein are memory devices based on negative differential impedance. The memory cells may be formed around vertical pillars of semiconductor material, with multiple independent gates formed along and coupled to the pillar at different heights. A region of a semiconductor with an opposite doping type from the pillar may be at the base of the pillar and coupled to a first bitline, and a highly-doped cap region with the same doping type as the pillar may be above the pillar and coupled to a second bitline.

### BACKGROUND

Embedded memory is important to the performance of modern system-on-a-chip (SoC) technology. Typically, memory assemblies (e.g., static random-access memory (SRAM) and dynamic random-access memory (DRAM)) include one or more memory arrays and control circuitry for the memory arrays in a single layer. Low power and high-density embedded memory is used in many different computer products and further improvements are always desirable.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 is an electric circuit diagram of an example 6-transistor (6T) memory cell.

FIG. 2 is an effective electric circuit diagram of a negative differential impedance memory cell, according to some embodiments of the present disclosure.

FIG. 3A is an example cross-section of a set of three memory devices, according to some embodiments of the present disclosure.

FIG. 3B is an example cross-section in the x-y plane through the cross-section of FIG. 3A illustrating a set of memory devices, according to some embodiments of the present disclosure.

FIGS. 4A-4C provide cross-sections illustrating electrical connections to the memory devices of FIGS. 3A and 3B, according to some embodiments of the present disclosure.

FIG. 5 illustrates example I-V curves for the memory devices illustrated in FIGS. 3 and 4, according to some embodiments of the present disclosure.

FIG. 6 is a top view of a wafer and dies that include one or more negative differential impedance memory cells in accordance with any of the embodiments disclosed herein.

FIG. 7 is a cross-sectional side view of an IC device that may include one or more negative differential impedance memory cells in accordance with any of the embodiments disclosed herein.

FIG. 8 is a cross-sectional side view of an IC device assembly that may include one or more negative differential impedance memory cells in accordance with any of the embodiments disclosed herein.

FIG. 9 is a block diagram of an example computing device that may include one or more negative differential impedance memory cells in accordance with any of the embodiments disclosed herein.

FIG. 10 is a block diagram of an example processing device that includes an IC device with one or more negative differential impedance memory cells in accordance with any of the embodiments disclosed herein.

### DETAILED DESCRIPTION

### Overview

The systems, methods and devices of this disclosure each have several innovative aspects, no single one of which is solely responsible for all desirable attributes disclosed herein. Details of one or more implementations of the subject matter described in this specification are set forth in the description below and the accompanying drawings.

Some memory devices may be considered “standalone” devices in that they are included in a chip that does not also include compute logic (where, as used herein, the term “compute logic devices” or simply “compute logic” or “logic devices,” refers to devices, e.g., transistors, for performing computing/processing operations). Other memory devices may be included in a chip along with compute logic and may be referred to as “embedded” memory devices. Using embedded memory to support compute logic may improve performance by bringing the memory and the compute logic closer together and eliminating interfaces that increase latency. Various embodiments of the present disclosure relate to embedded memory arrays, as well as corresponding methods and devices.

Some embodiments of the present disclosure may refer to SRAM and in particular, embedded SRAM (eSRAM). In general, memory cells/arrays described herein may be implemented as standalone SRAM devices, eSRAM devices, non-volatile SRAM devices, or other volatile or non-volatile memory cells/arrays.

An SRAM memory cell includes a plurality of transistors for storing a bit value or a memory state (e.g., logic “1” or “0”) of the cell, and one or more access transistors for controlling access to the cell (e.g., access to write information to the cell or access to read information from the cell). A typical SRAM memory cell is made up of 6 transistors and is, therefore, may be referred to as a “6T SRAM memory cell,” where 4 transistors are used to store a bit value and 2 transistors are access transistors, coupled to a bitline (BL) and a wordline (WL). Various SRAM memory cells have, conventionally, been implemented with transistors being front end of line (FEOL), logic-process based, transistors implemented in an upper-most layer of a semiconductor substrate.

One challenge in SRAM cells resides in that, given a usable surface area of a substrate, there are only so many FEOL transistors that can be formed in that area, placing a significant limitation on the density of memory cells incorporating such transistors. In conventional solutions, attempts to increase memory density have included decreasing the critical dimensions of the memory cells, which requires ever-increasing process complexity and cost, resulting in diminishing returns and expected slow pace of memory scaling for future nodes.

Embodiments of the present disclosure may improve on at least some of the challenges and issues described above by providing a memory cell formed around a single vertical pillar. As described herein, a memory device may include a semiconductor pillar coupled to three independently-controlled gates, e.g., three gates that wrap around the semiconductor pillar at different heights. The semiconductor pillar has a first dopant type (either n-type or p-type) and is formed over a semiconductor region of a second dopant type that is opposite the first. The semiconductor region may be underneath the gates. A more highly-doped region of the first dopant type is formed over the pillar, e.g., as a cap. The cap is located along the pillar at a height above the gates.

The memory device having this structure is a negative differential impedance device. The two ends of the pillar (e.g., the semiconductor region below the pillar and the cap over the pillar) form the two terminals of the negative differential impedance device. In general, a negative differential impedance device has an I-V curve with a region of negative resistance, or more generally, negative impedance. In general, impedance is a measure of opposition to the flow of alternating current in a circuit. Impedance encompasses resistance (which resists the flow of current) and reactance (which arises due to effects of capacitance in inductance).

The memory device described herein device exhibits hysteresis, where, for example, the I-V curve of the device (e.g., the resistance at a particular current level, where resistance may be detected by a drop in voltage across the device) changes in response to a switching voltage. More generally, a resistance, capacitance, and/or charge state of the memory device may change in response to an event (e.g., a charge event or avalanching event) within the memory device. The hysteresis effect causes a state of the device to be stored (e.g., with one I-V curve or impedance state corresponding to 1, and the other I-V curve or impedance state corresponding to 0), so that the device functions as an SRAM cell. A voltage can be applied to the middle gate to switch the device, e.g., to switch between the two IV curves or impedance states. Voltages may be applied to the top and/or bottom gates to apply a bias to the pillar, which can assist in switching the device between the two impedance states. For example, the top and bottom gates, along with the region of the pillar near the top and bottom gates, may act as access transistors for programming the memory device.

The vertical pillars described herein may be small structures, with a low amount of current passing through each individual pillar. In general, when semiconductor-devices operate at lower temperatures, they have improved performance. For example, electron mobility in semiconductors improves at lower temperatures, which can lead to increased drive currents across semiconductor regions, e.g., across a vertical pillar device. In addition, semiconductor devices at lower temperatures generally experience lower leakage than semiconductor devices operating at higher temperatures. These factors can allow small-scale devices to be used when an IC device is operating at a lower temperature.

For purposes of explanation, specific numbers, materials and configurations are set forth in order to provide a thorough understanding of the illustrative implementations. However, it will be apparent to one skilled in the art that the present disclosure may be practiced without the specific details or/and that the present disclosure may be practiced with only some of the described aspects. In other instances, well known features are omitted or simplified in order not to obscure the illustrative implementations.

In the following detailed description, reference is made to the accompanying drawings that form a part hereof, and in which is shown, by way of illustration, embodiments that may be practiced. It is to be understood that other embodiments may be utilized and structural or logical changes may be made without departing from the scope of the present disclosure. Therefore, the following detailed description is not to be taken in a limiting sense.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges. The meaning of “a,” “an,” and “the” include plural references. The meaning of “in” includes “in” and “on.”

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. The terms “substantially,” “close,” “approximately,” “near,” and “about,” generally refer to being within +/−20% of a target value, unless specified otherwise. Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

In the following detailed description, various aspects of the illustrative implementations will be described using terms commonly employed by those skilled in the art to convey the substance of their work to others skilled in the art. For example, as used herein, a “logic state” of a ferroelectric memory cell refers to one of a finite number of states that the cell can have, e.g. logic states “1” and “0,” each state represented by a different polarization of the ferroelectric material of the cell. In another example, as used herein, a “READ” and “WRITE” memory access or operations refer to, respectively, determining/sensing a logic state of a memory cell and programming/setting a logic state of a memory cell. In other examples, the term “connected” means a direct electrical or magnetic connection between the things that are connected, without any intermediary devices, while the term “coupled” means either a direct electrical or magnetic connection between the things that are connected or an indirect connection through one or more passive or active intermediary devices. The term “circuit” means one or more passive and/or active components that are arranged to cooperate with one another to provide a desired function. In yet another example, a “high-k dielectric” refers to a material having a higher dielectric constant (k) than silicon oxide. The terms “oxide,” “carbide,” “nitride,” etc. refer to compounds containing, respectively, oxygen, carbon, nitrogen, etc.

In the following, some descriptions may refer to a particular S/D region or contact being either a source region/contact or a drain region/contact. However, unless specified otherwise, which region/contact of a transistor is considered to be a source region/contact and which region/contact is considered to be a drain region/contact is not important because, as is common in the field of FETs, designations of source and drain are often interchangeable. Therefore, descriptions of some illustrative embodiments of the source and drain regions/contacts provided herein are applicable to embodiments where the designation of source and drain regions/contacts may be reversed.

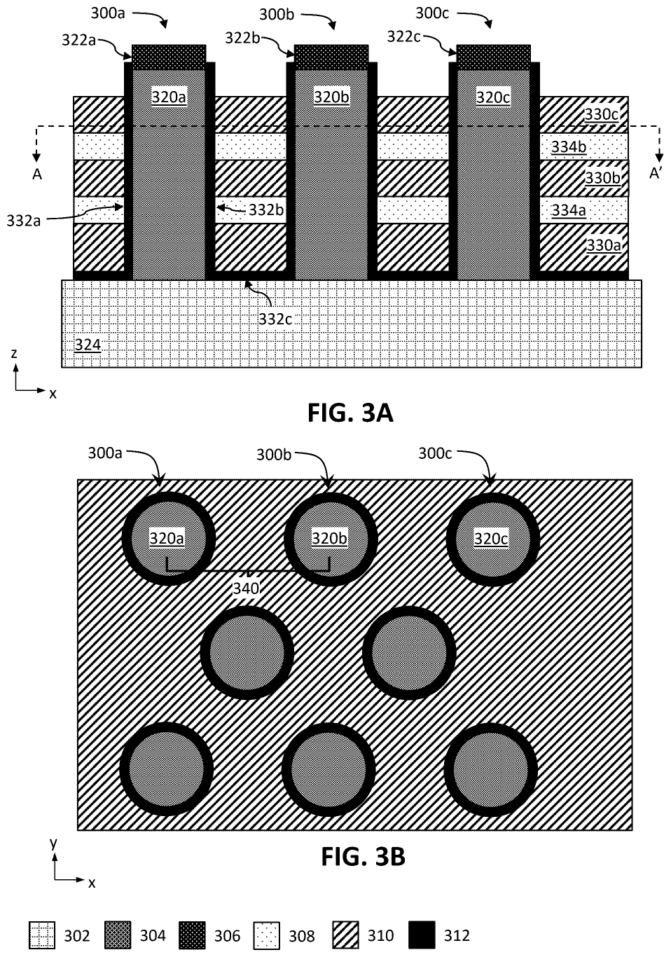

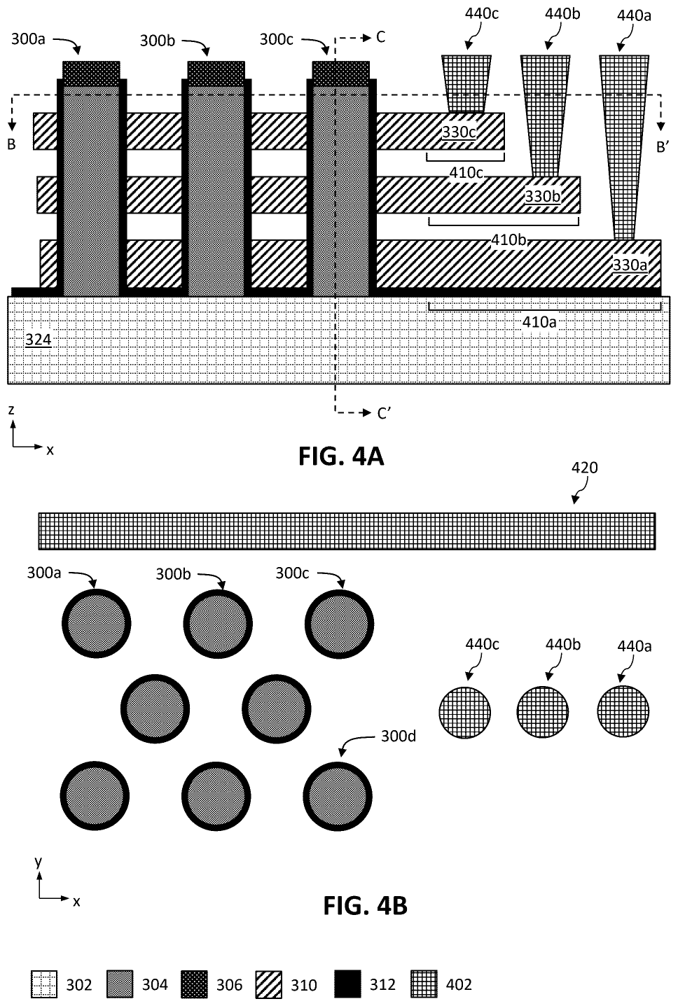

For convenience, if a collection of drawings designated with different letters are present, e.g., FIGS. 3A-3B, such a collection may be referred to herein without the letters, e.g., as “FIG. 3.”

### Example SRAM Memory Cell

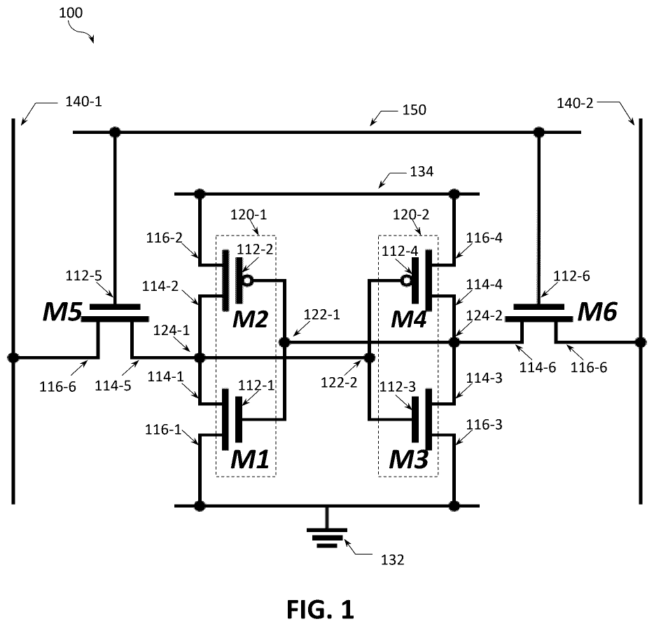

FIG. 1 is an electric circuit diagram of an example 6-transistor (6T) memory cell 100. The SRAM cell 100 includes transistors M1-M4 for storing a bit value or a memory state (e.g., logic “1” or “0”) of the cell, and two access transistors, M5 and M6, for controlling access to the cell (e.g., access to write information to the cell or access to read information from the cell 100). Each of the transistors M1-M6 may have any transistor architecture (e.g., planar or non-planar, FinFET, nanoribbon/nanowire, etc.).

In the SRAM cell 100, each bit may be stored on four transistors (M1, M2, M3, M4) that form two cross-coupled inverters 120, each having an input 122 and an output 124. The first inverter 120-1 may be formed by an NMOS transistor M1 and a PMOS transistor M2, while the second inverter 120-2 may be formed by an NMOS transistor M3 and a PMOS transistor M4. As shown in FIG. 1, the gate stack 112-1 of the transistor M1 may be coupled to the gate stack 112-2 of the transistor M2, and both of these gate stacks may be coupled to the input 122-1 of the first inverter 120-1. On the other hand, the first S/D region 114-1 of the transistor M1 may be coupled to the first S/D region 114-2 of the transistor M2, and both of these first S/D regions 114-1 and 114-2 may be coupled to the output 124-1 of the first inverter 120-1. Similarly, for the second inverter 120-2, the gate stack 112-3 of the transistor M3 may be coupled to the gate stack 112-4 of the transistor M4, and both of these gate stacks may be coupled to the input 122-2 of the second inverter 120-2, while the first S/D region 114-3 of the transistor M3 may be coupled to the first S/D region 114-4 of the transistor M4, and both of these first S/D regions 114-3 and 114-4 may be coupled to the output 124-2 of the second inverter 120-2. As also shown in FIG. 1, when the transistors M1 and M3 are NMOS transistors and when the transistors M2 and M4 are PMOS transistors as illustrated in FIG. 1, the second S/D regions 116-1 and 116-3 of the transistors M1 and M3 may be coupled to a ground voltage 132, while the second S/D regions 116-2 and 116-4 of the transistors M2 and M4 may be coupled to a supply voltage 134, e.g., VDD. In the embodiments of the SRAM cell 100 where the NMOS transistors shown in FIG. 1 are replaced with PMOS transistors and vice versa, the designation of the ground voltage 132 and the supply voltage 134 would be reversed as well, all of which embodiments being within the scope of the present disclosure.

The four transistors M1-M4 in the illustrated configuration form a stable storage cell for storing a bit value of 0 or 1. As further shown in FIG. 1, two additional access transistors, M5 and M6, may serve to control the access to the storage cell of the transistors M1-M4 during read and write operations. As shown in FIG. 1, the first S/D region 114-5 of the access transistor M5 may be coupled to the output 124-1 of the first inverter 120-1. Phrased differently, the first S/D region 114-5 of the access transistor M5 may be coupled to each of the first S/D region 114-1 of the transistor M1 and the first S/D region 114-2 of the transistor M2. The second S/D region 116-5 of the access transistor M5 may be coupled to a first BL 140-1. Thus, each of the first S/D region 114-1 of the transistor M1 and the first S/D region 114-2 of the transistor M2 may be coupled to the first BL 140-1 (e.g., via the access transistor M5). The gate 112-5 of the access transistor M5 may be coupled to a WL 150.

As further shown in FIG. 1, the first S/D region 114-6 of the access transistor M6 may be coupled to the output 124-2 of the second inverter 120-2. Phrased differently, the first S/D region 114-6 of the access transistor M6 may be coupled to each of the first S/D region 114-3 of the transistor M3 and the first S/D region 114-4 of the transistor M4. The second S/D region 116-6 of the access transistor M6 may be coupled to a second BL 140-2. Thus, each of the first S/D region 114-3 of the transistor M3 and the first S/D region 114-4 of the transistor M4 may be coupled to the second BL 140-2 (e.g., via the access transistor M6). The gate 112-6 of the access transistor M6 may be coupled to the WL 150. Thus, the gates 112-5 and 112-6 of both of the access transistors M5 and M6 may be coupled to a single, shared, WL, the WL 150.

As also shown in FIG. 1, the input 122-1 of the first inverter 120-1 may be coupled to the first S/D region 114-6 of the access transistor M6, while the input 122-2 of the second inverter 120-2 may be coupled to the first S/D region 114-5 of the access transistor M5. In other words, each of the gate stack 112-1 of the transistor M1 and the gate stack 112-2 of the transistor M2 may be coupled to the first S/D region 114-6 of the access transistor M6, while each of the gate stack 112-3 of the transistor M3 and the gate stack 112-4 of the transistor M4 may be coupled to the first S/D region 114-5 of the access transistor M5. Phrased differently, each of the gate stack 112-1 of the transistor M1 and the gate stack 112-2 of the transistor M2 may be coupled to the second BL 140-2 (e.g., via the access transistor M6), while each of the gate stack 112-3 of the transistor M3 and the gate stack 112-4 of the transistor M4 may be coupled to the first BL 140-1 (e.g., via the access transistor M5).

The WL 150 and the first and second BLs 140 may be used together to read and program (i.e., write to) the SRAM cell 100. In particular, access to the cell may be enabled by the WL 150 which controls the two access transistors M5 and M6 which, in turn, control whether the cell 100 should be connected to the BLs 140-1 and 140-2. During operation of the SRAM cell 100, a signal on the first BL 140-1 may be complementary to a signal on the second BL 140-2. The two BLs 140 may be used to transfer data for both read and write operations. In other embodiments of the SRAM cell 100, only a single BL 140 may be used, instead of two bitlines 140-1 and 140-2, although having one signal BL and one inverse, such as the two BLs 140, may help improve noise margins.

During read accesses, the BLs 140 are actively driven high and low by the inverters 120 in the SRAM cell 100. This may improve SRAM bandwidth compared to DRAM. The symmetric structure of the SRAMs cell 100 also allows for differential signaling, which may provide an improvement in detecting small voltage swings. Another difference with DRAM that may contribute to making SRAM faster than DRAM is that commercial chips accept all address bits at a time. By comparison, commodity DRAMs may have the address multiplexed in two halves, i.e. higher bits followed by lower bits, over the same package pins in order to keep their size and cost down.

Each of the WL 150 and the BLs 140, as well as intermediate elements coupling these lines to various terminals described herein, may be formed of any suitable electrically conductive material, which may include an alloy or a stack of multiple electrically conductive materials. In some embodiments, such electrically conductive materials may include one or more metals or metal alloys, with metals such as ruthenium, palladium, platinum, cobalt, nickel, hafnium, zirconium, titanium, tantalum, and aluminum. In some embodiments, such electrically conductive materials may include one or more electrically conductive alloys oxides or carbides of one or more metals.

### Example SRAM Memory Cell

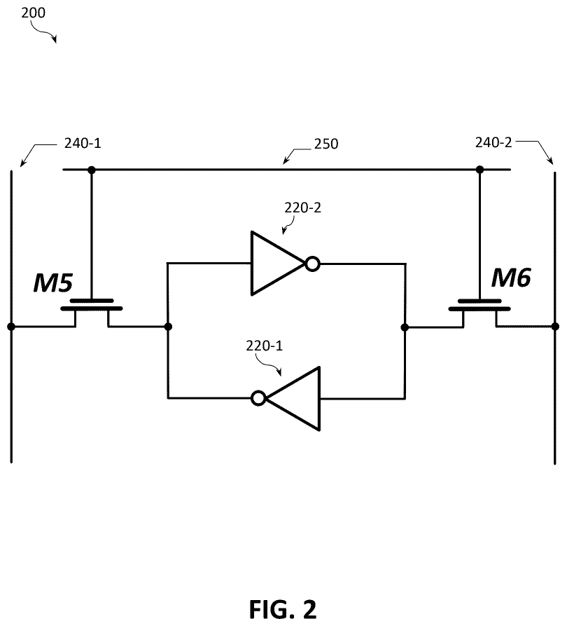

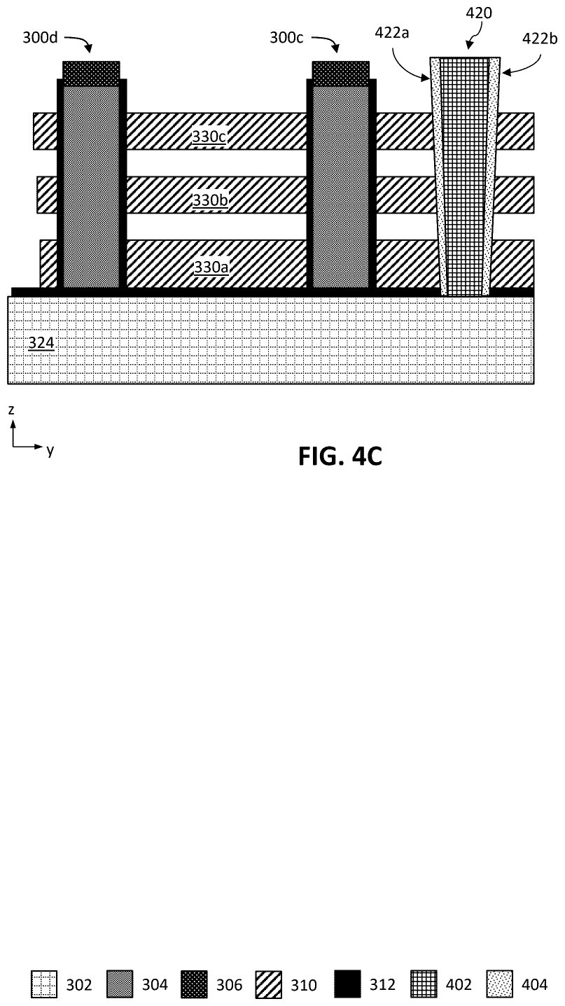

FIG. 2 is an effective electric circuit diagram of a negative differential impedance memory cell, e.g., the memory devices illustrated in FIGS. 3 and 4, described below. The SRAM cell 200 includes transistors M5 and M6, which are similar to transistors M5 and M6 of FIG. 1. Transistor M5 is coupled to a BL 240-1, which is similar to the BL 140-1, and a WL 250, which is similar to the WL 150. Transistor M6 is coupled to a BL 240-2, which is similar to the BL 140-2, and to the WL 250. The SRAM cell 200 further includes two cross-coupled inverters 220-1 and 220-2, which are positioned relative to the access transistors M5 and M6 in a similar manner to inverters 120-1 and 120-2.

The WL 250 and the first and second BLs 240 may be used together to read and program (i.e., write to) the SRAM cell 200. In particular, access to the cell may be enabled by the WL 250 which controls the two access transistors M5 and M6 which, in turn, control whether the cell 200 should be connected to the BLs 240-1 and 240-2. During operation of the SRAM cell 200, a signal on the first BL 240-1 may be complementary to a signal on the second BL 240-2. The two BLs 240 may be used to transfer data for both read and write operations. In other embodiments of the SRAM cell 200, only a single BL 240 may be used, instead of two bitlines 240-1 and 240-2, although having one signal BL and one inverse, such as the two BLs 240, may help improve noise margins.

During read accesses, the BLs 240 are actively driven high and low by the inverters 220 in the SRAM cell 200. The SRAM cell 200 may have the benefits over DRAM described above with respect to FIG. 1.

As described with respect to FIG. 1, each of the WL 250 and the BLs 240, as well as intermediate elements coupling these lines to various terminals described herein, may be formed of any suitable electrically conductive material, which may include an alloy or a stack of multiple electrically conductive materials. In some embodiments, such electrically conductive materials may include one or more metals or metal alloys, with metals such as ruthenium, palladium, platinum, cobalt, nickel, hafnium, zirconium, titanium, tantalum, and aluminum. In some embodiments, such electrically conductive materials may include one or more electrically conductive alloys oxides or carbides of one or more metals.

### Example Implementation of Multi-Gate Negative Differential Impedance Memory Cell

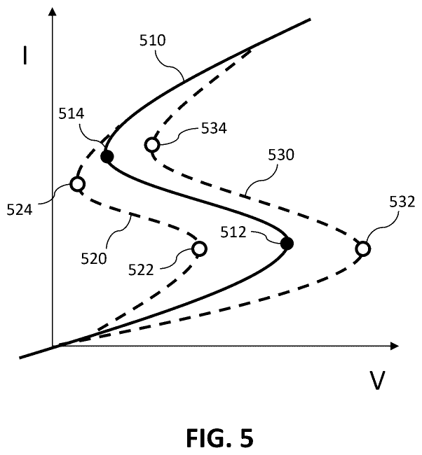

FIGS. 3 and 4 illustrate multi-gate negative differential impedance memory cells constructed around vertical semiconductor pillars. FIG. 2, discussed above, is an effective electrical circuit diagram of the memory cells illustrated in FIGS. 3 and 4. FIG. 5, described below, illustrates an example set of I-V curves for the memory cells described herein.

FIG. 3A is a cross-section through a set of three memory devices, and FIG. 3B is a cross-section in the x-y plane through plan AA′ in FIG. 3A, according to some embodiments of the present disclosure. A number of elements referred to in the description of FIGS. 3 and 4, and with reference numerals are illustrated in these figures with different patterns, with a legend at the bottom of the page showing the correspondence between the reference numerals and patterns. The legend illustrates that FIGS. 3A and 3B use different patterns to show a first semiconductor 302, a second semiconductor 304, a third semiconductor 306, a dielectric material 308, a gate electrode material 310, and a gate dielectric 312.

In the drawings, some example structures of various devices and assemblies described herein are shown with precise right angles and straight lines, but it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication.

In general, implementations of the present disclosure may be formed or carried out on a support structure. The semiconductor region 324, which includes the first semiconductor 302, may be a support structure or a portion of a support structure, with other features formed over the semiconductor region 324 (e.g., over the support structure). Alternatively, the semiconductor region 324 is formed over a support structure, or the semiconductor region 324 is formed within at least a portion of the support structure, e.g., by doping an upper layer of a semiconductor substrate to form the first semiconductor 302 for the semiconductor region 324.

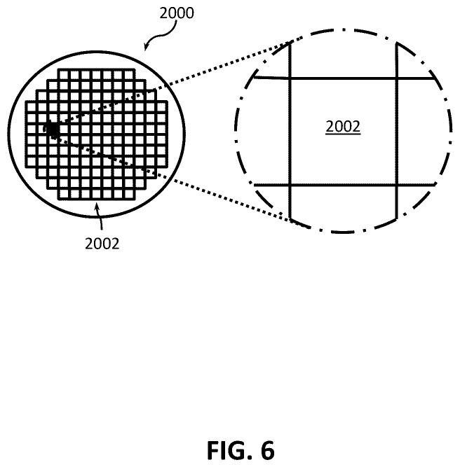

In general, the support structure may be, e.g., a substrate, a die, a wafer or a chip. For example, the support structure may be the wafer 2100 of FIG. 6, discussed below, and may be, or be included in, a die, e.g., the singulated die 2102 of FIG. 6, discussed below. The support structure extends along the x-y plane in the coordinate system shown in FIG. 3. In some embodiments, a support structure may be used during a fabrication process and later removed. For example, the devices 300 (optionally along with one or more layers over the devices 300, e.g., a metallization stack) may be attached to a second support structure (e.g., a carrier structure), and the support structure over which the devices 300 are formed may be removed to expose the back side of the devices 300. The semiconductor region 324, which may be formed over the support structure or formed in a top portion of the support structure, may remain attached to the devices 300, e.g., by removing a lower portion of the support structure.

In some embodiments, a support structure may be a substrate that includes silicon and/or hafnium. More generally, the support structure may be a semiconductor substrate composed of semiconductor material systems including, for example, N-type or P-type materials systems. In one implementation, the semiconductor substrate may be a crystalline substrate formed using a bulk silicon or a silicon-on-insulator (SOI) substructure. In other implementations, the semiconductor substrate may be formed using alternate materials, which may or may not be combined with silicon, that include, but are not limited to, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group III-V materials (i.e., materials from groups III and V of the periodic system of elements), group II-VI (i.e., materials from groups II and IV of the periodic system of elements), or group IV materials (i.e., materials from group IV of the periodic system of elements). In some embodiments, the substrate may be non-crystalline. In some embodiments, the support structure may be a printed circuit board (PCB) substrate. Although a few examples of materials from which the substrate may be formed are described here, any material that may serve as a foundation upon which a semiconductor device including one or more nanoribbon transistors, as described herein, may be built falls within the spirit and scope of the present disclosure.

FIG. 3A illustrates cross-sections through three memory devices 300a, 300b, and 300c, referred to jointly as memory devices 300 and also referred to as memory cells 300 or devices 300. Each device 300 is formed around a respective pillar 320a, 320, or 320c. Each device 300 further includes a cap 322 formed over the pillar 320. For example, the device 300 includes a cap 322a over the pillar 320a. A set of three gates 330a, 330b, and 330c are coupled to the pillars 320 at different heights in the z-direction along the pillars 320. The gates 330 may be considered a portion of each of the devices 300. The pillars 320 are formed over the semiconductor region 324. A portion of the semiconductor region 324 under each pillar 320 may be considered a portion of the respective memory device 300, e.g., a portion of the semiconductor region 324 under the pillar 320a is considered a portion of the memory device 300a.

The pillars 320 include the second semiconductor 304, and the caps 322 include the third semiconductor 306. Each of the first semiconductor 302, second semiconductor 304, and third semiconductor 306 any suitable semiconductor material. In general, the first semiconductor 302 and second semiconductor 304 may have opposite charge carrier types (i.e., one is n-type and the other p-type). The third semiconductor 306 has the same charge carrier type as the second semiconductor 304, and the third semiconductor 306 may be more highly doped than the second semiconductor 304.

In conductor and semiconductor materials, a charge carrier is a particle or quasiparticle that can move within the material, carrying a conductive charge and resulting in a net motion of particles through the material. In some semiconductors, the main charge carriers are electrons, while in others, the main charge carriers are electron holes (i.e., electron vacancies), generally referred to as holes. A semiconductor material or semiconductor region with holes as the primary charge carrier is referred to as p-type, and a semiconductor material or semiconductor region with electrons as the primary charge carrier is referred to as n-type. Doping may be used to create a p-type or n-type material; for example, silicon can be doped such that it is either n-type or p-type.

In general, the second semiconductor 304 may have a relatively low level of a dopant, e.g., a lower dopant concentration than the third semiconductor 306 and, in some cases, lower than the first semiconductor 302. For example, the first semiconductor 302 is a highly-doped n-type material, the second semiconductor 304 is a p-type material, and the third semiconductor 306 is a more highly-doped p-type material. As another example, the first semiconductor 302 is a highly-doped p-type material, the second semiconductor 304 is a low-doped n-type material, and the third semiconductor 306 is a highly-doped n-type material. The third semiconductor 306 may have a dopant concentration of about 1×10¹⁸ cm⁻³ or higher, e.g., 1×10²¹ cm⁻³. The first semiconductor 302 may have a similarly high doping concentration. The second semiconductor 304 may have a lower dopant concentration, e.g., between 1×10¹² cm⁻³ and 1×10¹⁷ cm⁻³.

One or more of the semiconductors 302, 304, and 306 may include a monocrystalline semiconductor, such as silicon (Si) or germanium (Ge). In some embodiments, one or more of the semiconductors 302, 304, and 306 may include a compound semiconductor with a first sub-lattice of at least one element from group III of the periodic table (e.g., Al, Ga, In), and a second sub-lattice of at least one element of group V of the periodic table (e.g., P, As, Sb).

For some embodiments, one or more of the semiconductors 302, 304, and 306 may include a III-V material having a high electron mobility, such as, but not limited to InGaAs, InP, InSb, and InAs. For some such embodiments, one or more of the semiconductors 302, 304, and 306 may be a ternary III-V alloy, such as InGaAs, GaAsSb, InAsP, or InPSb. For some InₓGa₁₋ₓAs embodiments, the In content (x) may be between 0.6 and 0.9, and may advantageously be at least 0.7 (e.g., In_{0.7}Ga_{0.3}As). For other embodiments, one or more of the semiconductor materials may be a group IV material having a high hole mobility, such as, but not limited to Ge or a Ge-rich SiGe alloy. For some example embodiments, one or more of the semiconductors 302, 304, and 306 may have a Ge content between 0.6 and 0.9, and may be at least 0.7.

In some embodiments, one or more of the semiconductors 302, 304, and 306 may be a thin-film material, such as a high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide. In general, one or more of the semiconductors 302, 304, and 306 may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, N- or P-type amorphous or polycrystalline silicon, germanium, indium gallium arsenide, silicon germanium, gallium nitride, aluminum gallium nitride, indium phosphite, and black phosphorus. Suitable dopants for one or more of the semiconductors 302, 304, and 306 may include gallium, indium, aluminum, fluorine, boron, phosphorus, arsenic, nitrogen, tantalum, tungsten, magnesium, etc.

As noted above, the pillars 320 are formed over the semiconductor region 324. For example, a layer of the second semiconductor 304 may be formed over the semiconductor region 324, followed by a layer of the third semiconductor 306, thus forming a stack of semiconductor materials. Regions of the stack of semiconductor materials for forming the pillars 320 may be blocked, while other regions of the second semiconductor 304 and third semiconductor 306 are removed, e.g., through etching. In some embodiments, the caps 322 may be deposited over the pillars 320 after etching the pillars 320.

The pillars 320 are semiconductor regions that extend in the z-direction in the coordinate system shown, e.g., in a direction perpendicular to a support structure. Said another way, the semiconductor region 324 generally extends in the x-direction and y-direction (e.g., the semiconductor region 324 extends in the x-direction in FIG. 3A), and the pillars 320 extend in a direction (here, the z-direction) that is perpendicular to the x- and y-directions. In the example of FIG. 3, the semiconductor region 324 has an upper surface that extends in the x-direction and y-direction, and the pillars 320 extend perpendicular to the upper surface of the semiconductor region 324. The pillars 320 extend in parallel to each other, e.g., pillars 320a, 320b, and 320c each extend in the z-direction.

The pillars 320 may have a height in the range of 50 to 500 nanometers. The caps 322 may have a height in the range of 5 to 100 nanometers. The pillars 320 and caps 322 may have a diameter (measured in the x-direction or y-direction) of between 20 and 100 nanometers, in some embodiments. The pillars 320 may be arranged at a pitch 340, where the pitch 340 refers to a center-to-center distance between the closest adjacent structures (e.g., between the pillars 320a and 320b). The pitch 340 of the pillars may be, in some examples, between 30 and 500 nanometers. In the example of FIG. 3B, the pillars 320 are arranged in a hexagonal pattern. In other embodiments, the pillars 320 may be arranged in a different pattern, e.g., in a square or rectangular pattern.

A layer of gate dielectric 312 may be deposited around the pillars 320. As illustrated in FIG. 3A, two layers 332a and 332b of the gate dielectric 312 are on either side of the pillar 320a, between the pillar 320a and the gates 330. As illustrated in FIG. 3B, the gate dielectric 312 may enclose or encircle the sidewall of the pillars 320. In the example of FIG. 3A, a layer of the gate dielectric 312 is over the semiconductor region 324, e.g., the gate dielectric region 332c is over the semiconductor region 324 in an area between the pillars 320a and 320b. In the example of FIG. 3A, the gate dielectric 312 does not extend to the tops of the caps 322; in other embodiments, the gate dielectric 312 may extend up the sidewalls of the caps 322.

The gate dielectric 312 may include one or more high-k dielectric materials and may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric 312 may include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate. In some embodiments, an annealing process may be carried out on the gate dielectric 312 during manufacture of the devices 300 to improve the quality of the gate dielectric 312. In some embodiments, the gate dielectric 312 may have a thickness between about 0.5 nanometers and 3 nanometers, including all values and ranges therein, e.g., between about 1 and 3 nanometers, or between about 1 and 2 nanometers.

The set of three gates 330a, 330b, and 330c are electrically coupled to the pillars 320 at different heights in the z-direction along the pillars 320. Each of the gates 330 includes the gate electrode material 310, which is a conductive material; the gates 330 are conductive structures, which are coupled to the pillars 320 through the gate dielectric 312. The gate dielectric 312 is between the pillars 320 and the gates 330. A first gate 330a is over the semiconductor region 324 and, in particular, over the layer of gate dielectric 312 (e.g., the gate dielectric region 332c) formed over the semiconductor region 324. The first gate 330a surrounds a lower portion or base of each of the pillars 320. A second gate 330b is over the first gate 330a, around or near to a center portion of the pillars 320. The second gate 330b surrounds a middle portion of each of the pillars 320. A third gate 330c is near the top of the pillars 320, under the caps 322 and over the second gate 330b. The third gate 330c surrounds an upper portion of each of the pillars 320. The gates 330a, 330b, and 330c extend in parallel to each other; each of the gates 330a, 330b, and 330c extend in the x-direction (as shown in FIGS. 3A and 3B) and in the y-direction as shown in FIG. 3B) at different z-heights. The gates 330 extend perpendicular to the pillars 320, which extend in the z-direction, as discussed above.

Layers 334a and 334b of the dielectric material 308 are between adjacent ones of the gates 330. In particular, layer 334a of the dielectric material 308 is between the first gate 330a and the second gate 330b, and layer 334b of the dielectric material 308 is between the third gate 330c and the second gate 330b. The gates 330a, 330b, and 330c are thus physically separated and electrically independent, and may be independently controlled.

The gate electrode material 310 may include at least one P-type work function metal or N-type work function metal. For devices with p-type doping in the second semiconductor 304 of the pillars 320, metals that may be used for the gate electrode material 310 may include, but are not limited to, ruthenium, palladium, platinum, cobalt, nickel, and conductive metal oxides (e.g., ruthenium oxide). For devices with n-type doping in the second semiconductor 304 of the pillars 320, metals that may be used for the gate electrode material 310 include, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide). In some embodiments, the gate electrode material 310 may include a stack of two or more metal layers, where one or more metal layers are WF metal layers and at least one metal layer is a fill metal layer.

Referring back to FIG. 2, the gate 330a and portion of the pillar 320 proximate to the gate 330a (e.g., the lower portion of the pillar 320) may act as a first access transistor, e.g., the transistor M5. The gate 330c and portion of the pillar 320 proximate to the gate 330c (e.g., the upper portion of the pillar 320) may act as a second access transistor, e.g., the transistor M6. The gates 330a and 330c may be coupled to the WL 250, as shown in FIG. 2, while the gate 330b may be independently controlled. The semiconductor region 324 may be coupled to a first BL (e.g., BL 240-1) and the cap 322 may be coupled to a second BL (e.g., BL 240-2).

A voltage applied to the gate 330b may be modulated to control a state of the memory device 300, e.g., to cause the inverters 220 to store a state of “1” (at one impedance state of the memory device 300) or a state of “0” (at the other impedance state of the memory device 300). Alternatively, the BL and WL may be modulated to control the state of the memory device 300, and a bias voltage may be applied to the second gate 330b in different situations to make it more difficult to change the state (e.g., to increase the switching voltage to improve retention) or easier to change the state (e.g., to lower the switching voltage to increase switching speed). Applying a voltage to the pillar 320, e.g., at gates of M5 and M6 (i.e., around the upper and lower portions of the pillar 320) and, at some cases, at the gate 330b, may lead to positive feedback, an avalanche effect, or a charge event within the pillar 320. This event can cause the pillar 320 to change impedance states, i.e., to change the differential voltage across the memory device 300.

FIGS. 4A-4C provide cross-sections illustrating electrical connections to the memory devices of FIGS. 3A and 3B, according to some embodiments of the present disclosure. FIG. 4A is an expanded cross-section of the view shown in FIG. 3A. FIG. 4A illustrates the three memory devices 300a-300a, which are physically and electrically connected in the horizontal direction by gates 330a, 330b, and 330c. As noted above, the gates 330 extend in a direction perpendicular to the pillars of the memory devices 300. The gates 330 extend in the x-direction, as shown in FIG. 4A, and also may extend in the y-direction, as shown in FIG. 4C.

The gates 330 are isolated from one another (e.g., by the layers 334 of the dielectric material 308, described above but not specifically illustrated in FIG. 4) and configured to enable independent electrical connections. In this example, the gates 330 have extension regions 410 extending in the x-direction in the coordinate shown to different lengths, so that the extension regions 410 of the gates 330 resemble a staircase. Vias 440 at different positions in the x-direction can then connect to the different extension regions 410 or different “steps” of the staircase.

Each of the gates (e.g., gates 330a, 330b, and 330c) may be considered to be in a separate layer (e.g., a separate gate layer), and the extension regions for forming the gate line-via connections extends along the gate layer. Each extension region 410 is coupled to a respective gate via 440, and each of the gate vias 440 extends down from a front side of the device. The gate via 440c is coupled to the extension region 410c of the top gate 330c, and each subsequent gate via 440b and 440a is coupled to the next gate line in a lower gate layer. For example, the gate via 440a extends through the upper two gate layers. The gate vias 440 may have different lengths, i.e., heights in the z-direction. For example, the gate via 440c has a shorter height, also referred to as shorter length, than the gate via 440a. The vias 440 may be formed from any conductive material 402, such as copper or another metal. In some embodiments, the vias 440 include multiple layers, e.g., one or more liner layers and a fill layer.

FIG. 4B illustrates the cross-section through the plane BB′ of FIG. 4A. FIG. 4B illustrates the tops of the pillars 320 and the vias 440. FIG. 4B illustrates cross-sections through the three devices 300a-300c in FIG. 4A, as well as additional pillars of additional devices, e.g., the devices shown in FIG. 3B. One of these additional devices is labelled 300d. FIG. 4B further illustrates a via 420 that extends through the gate layers to the semiconductor region 324. The via 420 includes the conductive material 402 of the vias 440, but in other examples, the vias 420 and 440 may include different conductive materials. In this example, the via 420 extends through the front-side of the device. In other embodiments, a back-side via may be provided, connecting to the underside of the semiconductor region 324.

FIG. 4C illustrates the cross-section through the plane CC′ of FIG. 4A. FIG. 4C illustrates the devices 300c and 300d and the vias 420. As illustrated in FIG. 4C, two layers 422a and 422b of a dielectric material 404 are on either side of the via 420, physically and electrically separating the via 420 from the gates 330 so that the semiconductor region 324 may be independently controlled. The dielectric material 404 may include any dielectric material described herein.

### Example I-V Curves for Memory Cell

FIG. 5 illustrates example I-V curves for the memory devices illustrated in FIGS. 3 and 4, according to some embodiments of the present disclosure. FIG. 5 illustrate voltage V along the x-axis and current I along the y-axis. FIG. 5 includes an I-V curve 510 of a negative differential voltage device, e.g., a negative differential voltage device that does not experience the impedance switching hysteresis effect described above. In general, in a negative differential voltage device, voltage is a single valued function of the current, but the current is a multivalued function of the voltage. The negative resistance region is between the points 512 and 514 along the curve 510; in this portion of the curve, the current decreases as the voltage increases.

The devices 300 illustrated in FIGS. 3 and 4 exhibit two different I-V curves depending on the impedance state. In this example, a first shifted curve 520 is generally to the left of the curve 510, and a second shifted curve 530 is generally to the right of the right of the curve 530. Each of the curves 520 and 530 includes a negative resistance region; the first shifted curve 520 has a negative resistance region between the points 522 and 524, and the second shifted curve 530 has a negative resistance region between the points 532 and 534. A device 300 may switch between the curves 520 (representing a first impedance state) and 530 (representing a second impedance state). The voltage range for the negative impedance region is different for the two shifted curves 520 and 530. Thus, the I-V characteristic of the device 300 may be used to determine which state the device 300 is in.

### Example Devices

The circuit devices with negative differential impedance memory cells disclosed herein may be included in any suitable electronic device. FIGS. 6-10 illustrate various examples of apparatuses that may include the one or more memory cells disclosed herein.

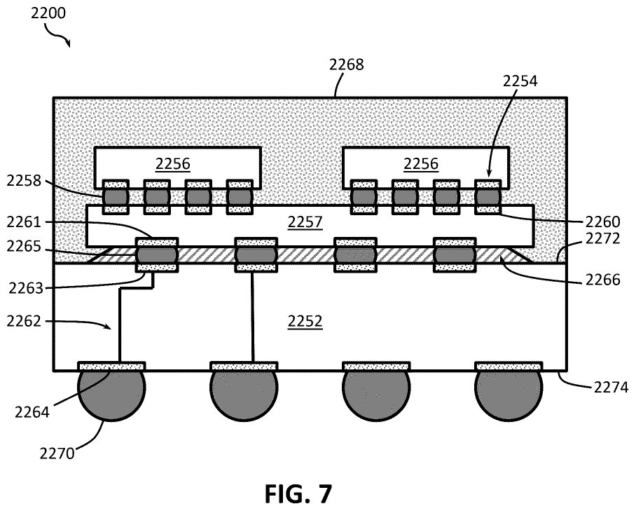

FIG. 6 illustrates top views of a wafer 2100 and dies 2102 that may include one or more negative differential impedance memory cells in accordance with any of the embodiments disclosed herein. In some embodiments, the dies 2102 may be included in an IC package, in accordance with any of the embodiments disclosed herein. For example, any of the dies 2102 may serve as any of the dies 2256 in an IC package 2200 shown in FIG. 7. The wafer 2100 may be composed of semiconductor material and may include one or more dies 2102 having IC structures formed on a surface of the wafer 2100. Each of the dies 2102 may be a repeating unit of a semiconductor product that includes any suitable IC (e.g., ICs including one or more negative differential impedance memory cells as described herein). After the fabrication of the semiconductor product is complete (e.g., after manufacture of any embodiment of the IC devices as described herein), the wafer 2100 may undergo a singulation process in which each of the dies 2102 is separated from one another to provide discrete “chips” of the semiconductor product. In particular, devices that include one or more negative differential impedance memory cells as disclosed herein may take the form of the wafer 2100 (e.g., not singulated) or the form of the die 2102 (e.g., singulated). The die 2102 may include supporting circuitry to route electrical signals to various memory cells, transistors, capacitors, as well as any other IC components. In some embodiments, the wafer 2100 or the die 2102 may implement or include a memory device (e.g., a hysteretic memory device), a logic device (e.g., an AND, OR, NAND, or NOR gate), or any other suitable circuit element. Multiple ones of these devices may be combined on a single die 2102. For example, a memory array formed by multiple memory devices may be formed on a same die 2102 as a processing device (e.g., the processing device 2402 of FIG. 7) or other logic that is configured to store information in the memory devices or execute instructions stored in the memory array.

FIG. 7 is a side, cross-sectional view of an example IC package 2200 that may include one or more negative differential impedance memory cells in accordance with any of the embodiments disclosed herein. In some embodiments, the IC package 2200 may be a system-in-package (SiP).

The package substrate 2252 may be formed of a dielectric material (e.g., a ceramic, a buildup film, an epoxy film having filler particles therein, etc.), and may have conductive pathways extending through the dielectric material between the face 2272 and the face 2274, or between different locations on the face 2272, and/or between different locations on the face 2274.

The package substrate 2252 may include conductive contacts 2263 that are coupled to conductive pathways 2262 through the package substrate 2252, allowing circuitry within the dies 2256 and/or the interposer 2257 to electrically couple to various ones of the conductive contacts 2264 (or to other devices included in the package substrate 2252, not shown).

The IC package 2200 may include an interposer 2257 coupled to the package substrate 2252 via conductive contacts 2261 of the interposer 2257, first-level interconnects 2265, and the conductive contacts 2263 of the package substrate 2252. The first-level interconnects 2265 illustrated in FIG. 7 are solder bumps, but any suitable first-level interconnects 2265 may be used. In some embodiments, no interposer 2257 may be included in the IC package 2200; instead, the dies 2256 may be coupled directly to the conductive contacts 2263 at the face 2272 by first-level interconnects 2265.

The IC package 2200 may include one or more dies 2256 coupled to the interposer 2257 via conductive contacts 2254 of the dies 2256, first-level interconnects 2258, and conductive contacts 2260 of the interposer 2257. The conductive contacts 2260 may be coupled to conductive pathways (not shown) through the interposer 2257, allowing circuitry within the dies 2256 to electrically couple to various ones of the conductive contacts 2261 (or to other devices included in the interposer 2257, not shown). The first-level interconnects 2258 illustrated in FIG. 7 are solder bumps, but any suitable first-level interconnects 2258 may be used. As used herein, a “conductive contact” may refer to a portion of electrically conductive material (e.g., metal) serving as an interface between different components; conductive contacts may be recessed in, flush with, or extending away from a surface of a component, and may take any suitable form (e.g., a conductive pad or socket).

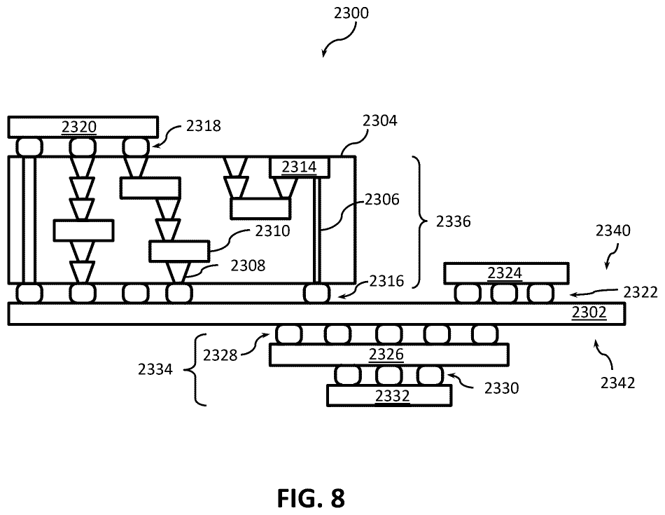

In some embodiments, an underfill material 2266 may be disposed between the package substrate 2252 and the interposer 2257 around the first-level interconnects 2265, and a mold compound 2268 may be disposed around the dies 2256 and the interposer 2257 and in contact with the package substrate 2252. In some embodiments, the underfill material 2266 may be the same as the mold compound 2268. Example materials that may be used for the underfill material 2266 and the mold compound 2268 are epoxy mold materials, as suitable. Second-level interconnects 2270 may be coupled to the conductive contacts 2264. The second-level interconnects 2270 illustrated in FIG. 7 are solder balls (e.g., for a ball grid array arrangement), but any suitable second-level interconnects 22770 may be used (e.g., pins in a pin grid array arrangement or lands in a land grid array arrangement). The second-level interconnects 2270 may be used to couple the IC package 2200 to another component, such as a circuit board (e.g., a motherboard), an interposer, or another IC package, as known in the art and as discussed below with reference to FIG. 8.

The dies 2256 may take the form of any of the embodiments of the die 2102 discussed herein (e.g., may include any of the embodiments of the IC devices with one or more negative differential impedance memory cells as described herein). In embodiments in which the IC package 2200 includes multiple dies 2256, the IC package 2200 may be referred to as a multi-chip package (MCP). The dies 2256 may include circuitry to perform any desired functionality. For example, one or more of the dies 2256 may be logic dies (e.g., silicon-based dies), and one or more of the dies 2256 may be memory dies (e.g., high bandwidth memory), including embedded memory dies as described herein. In some embodiments, any of the dies 2256 may include one or more IC devices with one or more negative differential impedance memory cells, e.g., as discussed above; in some embodiments, at least some of the dies 2256 may not include any negative differential impedance memory cells.

The IC package 2200 illustrated in FIG. 7 may be a flip chip package, although other package architectures may be used. For example, the IC package 2200 may be a ball grid array (BGA) package, such as an embedded wafer-level ball grid array (eWLB) package. In another example, the IC package 2200 may be a wafer-level chip scale package (WLCSP) or a panel fan-out (FO) package. Although two dies 2256 are illustrated in the IC package 2200 of FIG. 7, an IC package 2200 may include any desired number of the dies 2256. An IC package 2200 may include additional passive components, such as surface-mount resistors, capacitors, and inductors disposed on the first face 2272 or the second face 2274 of the package substrate 2252, or on either face of the interposer 2257. More generally, an IC package 2200 may include any other active or passive components known in the art.

FIG. 8 is a cross-sectional side view of an IC device assembly 2300 that may include components having one or more negative differential impedance memory cells in accordance with any of the embodiments disclosed herein. The IC device assembly 2300 includes a number of components disposed on a circuit board 2302 (which may be, e.g., a motherboard). The IC device assembly 2300 includes components disposed on a first face 2340 of the circuit board 2302 and an opposing second face 2342 of the circuit board 2302; generally, components may be disposed on one or both faces 2340 and 2342. In particular, any suitable ones of the components of the IC device assembly 2300 may include any of one or more negative differential impedance memory cells in accordance with any of the embodiments disclosed herein; e.g., any of the IC packages discussed below with reference to the IC device assembly 2300 may take the form of any of the embodiments of the IC package 2200 discussed above with reference to FIG. 7 (e.g., may include one or more negative differential impedance memory cells provided on a die 2256).

In some embodiments, the circuit board 2302 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 2302. In other embodiments, the circuit board 2302 may be a non-PCB substrate.

The IC device assembly 2300 illustrated in FIG. 8 includes a package-on-interposer structure 2336 coupled to the first face 2340 of the circuit board 2302 by coupling components 2316. The coupling components 2316 may electrically and mechanically couple the package-on-interposer structure 2336 to the circuit board 2302, and may include solder balls (e.g., as shown in FIG. 8), male and female portions of a socket, an adhesive, an underfill material, and/or any other suitable electrical and/or mechanical coupling structure.

The package-on-interposer structure 2336 may include an IC package 2320 coupled to an interposer 2304 by coupling components 2318. The coupling components 2318 may take any suitable form for the application, such as the forms discussed above with reference to the coupling components 2316. The IC package 2320 may be or include, for example, a die (the die 2102 of FIG. 6), an IC device, or any other suitable component. In particular, the IC package 2320 may include one or more negative differential impedance memory cells as described herein. Although a single IC package 2320 is shown in FIG. 8, multiple IC packages may be coupled to the interposer 2304; indeed, additional interposers may be coupled to the interposer 2304. The interposer 2304 may provide an intervening substrate used to bridge the circuit board 2302 and the IC package 2320. Generally, the interposer 2304 may spread a connection to a wider pitch or reroute a connection to a different connection. For example, the interposer 2304 may couple the IC package 2320 (e.g., a die) to a BGA of the coupling components 2316 for coupling to the circuit board 2302. In the embodiment illustrated in FIG. 8, the IC package 2320 and the circuit board 2302 are attached to opposing sides of the interposer 2304; in other embodiments, the IC package 2320 and the circuit board 2302 may be attached to a same side of the interposer 2304. In some embodiments, three or more components may be interconnected by way of the interposer 2304.

The interposer 2304 may be formed of an epoxy resin, a fiberglass-reinforced epoxy resin, a ceramic material, or a polymer material such as polyimide. In some implementations, the interposer 2304 may be formed of alternate rigid or flexible materials that may include the same materials described above for use in a semiconductor substrate, such as silicon, germanium, and other group III-V and group IV materials. The interposer 2304 may include metal interconnects 2308 and vias 2310, including but not limited to through-silicon vias (TSVs) 2306. The interposer 2304 may further include embedded devices 2314, including both passive and active devices. Such devices may include, but are not limited to, capacitors, decoupling capacitors, resistors, inductors, fuses, diodes, transformers, sensors, electrostatic discharge (ESD) protection devices, and memory devices. More complex devices such as radio frequency (RF) devices, power amplifiers, power management devices, antennas, arrays, sensors, and microelectromechanical systems (MEMS) devices may also be formed on the interposer 2304. The package-on-interposer structure 2336 may take the form of any of the package-on-interposer structures known in the art.

The IC device assembly 2300 may include an IC package 2324 coupled to the first face 2340 of the circuit board 2302 by coupling components 2322. The coupling components 2322 may take the form of any of the embodiments discussed above with reference to the coupling components 2316, and the IC package 2324 may take the form of any of the embodiments discussed above with reference to the IC package 2320.

The IC device assembly 2300 illustrated in FIG. 8 includes a package-on-package structure 2334 coupled to the second face 2342 of the circuit board 2302 by coupling components 2328. The package-on-package structure 2334 may include an IC package 2326 and an IC package 2332 coupled together by coupling components 2330 such that the IC package 2326 is disposed between the circuit board 2302 and the IC package 2332. The coupling components 2328 and 2330 may take the form of any of the embodiments of the coupling components 2316 discussed above, and the IC packages 2326 and 2332 may take the form of any of the embodiments of the IC package 2320 discussed above. The package-on-package structure 2334 may be configured in accordance with any of the package-on-package structures known in the art.

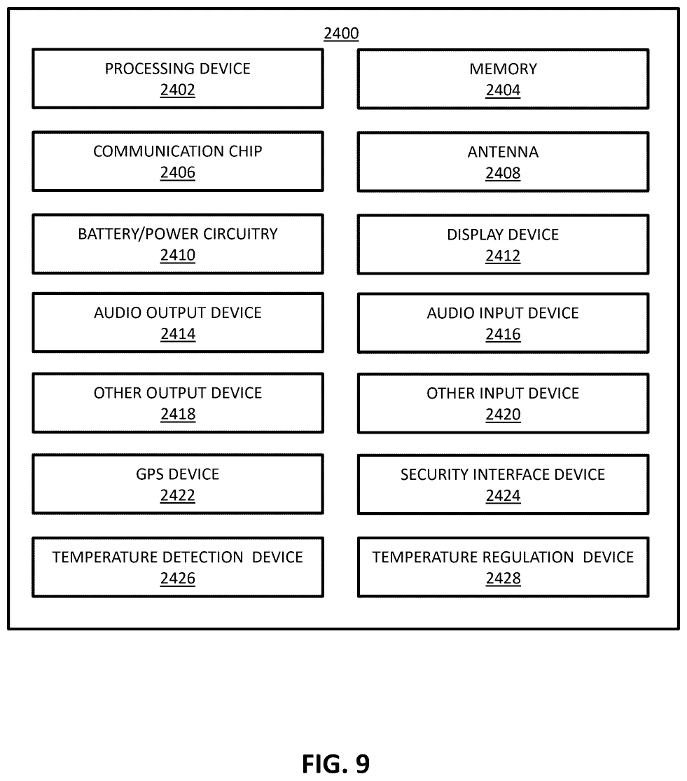

FIG. 9 is a block diagram of an example computing device 2400 that may include one or more components including one or more IC devices with one or more negative differential impedance memory cells in accordance with any of the embodiments disclosed herein. For example, any suitable ones of the components of the computing device 2400 may include a die (e.g., the die 2102 of FIG. 6) having one or more negative differential impedance memory cells as described herein. Any one or more of the components of the computing device 2400 may include, or be included in, an IC package 2200 of FIG. 7 or an IC device 2300 of FIG. 8.

A number of components are illustrated in FIG. 9 as included in the computing device 2400, but any one or more of these components may be omitted or duplicated, as suitable for the application. In some embodiments, some or all of the components included in the computing device 2400 may be attached to one or more motherboards. In some embodiments, some or all of these components are fabricated onto a single system-on-a-chip (SoC) die.

Additionally, in various embodiments, the computing device 2400 may not include one or more of the components illustrated in FIG. 9, but the computing device 2400 may include interface circuitry for coupling to the one or more components. For example, the computing device 2400 may not include a display device 2412, but may include display device interface circuitry (e.g., a connector and driver circuitry) to which a display device 2412 may be coupled. In another set of examples, the computing device 2400 may not include an audio input device 2416 or an audio output device 2414, but may include audio input or output device interface circuitry (e.g., connectors and supporting circuitry) to which an audio input device 2416 or audio output device 2414 may be coupled.

The computing device 2400 may include a processing device 2402 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 2402 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The computing device 2400 may include a memory 2404, which may itself include one or more memory devices such as volatile memory (e.g., DRAM), nonvolatile memory (e.g., read-only memory (ROM)), flash memory, solid state memory, and/or a hard drive. In some embodiments, the memory 2404 may include memory that shares a die with the processing device 2402. This memory may be used as cache memory and may include embedded DRAM (eDRAM) or spin transfer torque magnetic random-access memory (STT-MRAM).

In some embodiments, the computing device 2400 may include a communication chip 2406 (e.g., one or more communication chips). For example, the communication chip 2406 may be configured for managing wireless communications for the transfer of data to and from the computing device 2400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 2406 may implement any of a number of wireless standards or protocols, including but not limited to Institute for Electrical and Electronic Engineers (IEEE) standards including Wi-Fi (IEEE 1402.11 family), IEEE 1402.16 standards (e.g., IEEE 1402.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 1402.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 1402.16 standards. The communication chip 2406 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 2406 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 2406 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 2406 may operate in accordance with other wireless protocols in other embodiments. The computing device 2400 may include an antenna 2408 to facilitate wireless communications and/or to receive other wireless communications (such as AM or FM radio transmissions).

In some embodiments, the communication chip 2406 may manage wired communications, such as electrical, optical, or any other suitable communication protocols (e.g., the Ethernet). As noted above, the communication chip 2406 may include multiple communication chips. For instance, a first communication chip 2406 may be dedicated to shorter-range wireless communications such as Wi-Fi or Bluetooth, and a second communication chip 2406 may be dedicated to longer-range wireless communications such as global positioning system (GPS), EDGE, GPRS, CDMA, WiMAX, LTE, EV-DO, or others. In some embodiments, a first communication chip 2406 may be dedicated to wireless communications, and a second communication chip 2406 may be dedicated to wired communications.

The computing device 2400 may include a battery/power circuitry 2410. The battery/power circuitry 2410 may include one or more energy storage devices (e.g., batteries or capacitors) and/or circuitry for coupling components of the computing device 2400 to an energy source separate from the computing device 2400 (e.g., AC line power).

The computing device 2400 may include a display device 2412 (or corresponding interface circuitry, as discussed above). The display device 2412 may include any visual indicators, such as a heads-up display, a computer monitor, a projector, a touchscreen display, a liquid crystal display (LCD), a light-emitting diode display, or a flat panel display, for example.

The computing device 2400 may include an audio output device 2414 (or corresponding interface circuitry, as discussed above). The audio output device 2414 may include any device that generates an audible indicator, such as speakers, headsets, or earbuds, for example.

The computing device 2400 may include an audio input device 2416 (or corresponding interface circuitry, as discussed above). The audio input device 2416 may include any device that generates a signal representative of a sound, such as microphones, microphone arrays, or digital instruments (e.g., instruments having a musical instrument digital interface (MIDI) output).

The computing device 2400 may include an other output device 2418 (or corresponding interface circuitry, as discussed above). Examples of the other output device 2418 may include an audio codec, a video codec, a printer, a wired or wireless transmitter for providing information to other devices, or an additional storage device.

The computing device 2400 may include an other input device 2420 (or corresponding interface circuitry, as discussed above). Examples of the other input device 2420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 2400 may include a GPS device 2422 (or corresponding interface circuitry, as discussed above). The GPS device 2422 may be in communication with a satellite-based system and may receive a location of the computing device 2400, as known in the art.

The computing device 2400 may include a security interface device 2424. The security interface device 2424 may include any device that provides security features for the computing device 2400 or for any individual components therein (e.g., for the processing device 2402 or for the memory 2404). Examples of security features may include authorization, access to digital certificates, access to items in keychains, etc. Examples of the security interface device 2424 may include a software firewall, a hardware firewall, an antivirus, a content filtering device, or an intrusion detection device.

In some embodiments, the computing device 2400 may include a temperature detection device 2426 and a temperature regulation device 2428.

The temperature detection device 2426 may include any device capable of determining temperatures of the computing device 2400 or of any individual components therein (e.g., temperatures of the processing device 2402 or of the memory 2404). In various embodiments, the temperature detection device 2426 may be configured to determine temperatures of an object (e.g., the computing device 2400, components of the computing device 2400, devices coupled to the computing device, etc.), temperatures of an environment (e.g., a data center that includes, is controlled by, or otherwise associated with the computing device 2400), and so on. The temperature detection device 2426 may include one or more temperature sensors. Different temperature sensors of the temperature detection device 2426 may have different locations within and around the computing device 2400. A temperature sensor may generate data (e.g., digital data) representing detected temperatures and provide the data to another device, e.g., to the temperature regulation device 2428, the processing device 2402, the memory 2404, etc. In some embodiments, a temperature sensor of the temperature detection device 2426 may be turned on or off, e.g., by the processing device 2402 or an external system. The temperature sensor detects temperatures when it is on and does not detect temperatures when it is off. In other embodiments, a temperature sensor of the temperature detection device 2426 may detect temperatures continuously and automatically or detect temperatures at predefined times or at times triggered by an event associated with the computing device 2400 or any components therein.

The temperature regulation device 2428 may include any device configured to change (e.g., decrease) temperatures, e.g., based on one or more target temperatures and/or based on temperature measurements performed by the temperature detection device 2426. A target temperature may be a preferred temperature. A target temperature may depend on a setting in which the computing device 2400 operates. In some embodiments, the target temperature may be 200 Kelvin degrees or lower. In some embodiments, the target temperature may be 20 Kelvin degrees or lower, or 5 Kelvin degrees or lower. Target temperatures for different objects and different environments of, or associated with, the computing device 2400 can be different. In some embodiments, cooling provided by the temperature regulation device 2428 may be a multi-stage process with temperatures ranging from room temperature to 4K or lower.

In some embodiments, the temperature regulation device 2428 may include one or more cooling devices. Different cooling device may have different locations within and around the computing device 2400. A cooling device of the temperature regulation device 2428 may be associated with one or more temperature sensors of the temperature detection device 2426 and may be configured to operate based on temperatures detected the temperature sensors. For instance, a cooling device may be configured to determine whether a detected ambient temperature is above the target temperature or whether the detected ambient temperature is higher than the target temperature by a predetermined value or determine whether any other temperature-related condition associated with the temperature of the computing device 2400 is satisfied. In response to determining that one or more temperature-related condition associated with the temperature of the computing device 2400 are satisfied (e.g., in response to determining that the detected ambient temperature is above the target temperature), a cooling device may trigger its cooling mechanism and start to decrease the ambient temperature. Otherwise, the cooling device does not trigger any cooling. A cooling device of the temperature regulation device 2428 may operate with various cooling mechanisms, such as evaporation cooling, radiation cooling, conduction cooling, convection cooling, other cooling mechanisms, or any combination thereof. A cooling device of the temperature regulation device 2428 may include a cooling agent, such as a water, oil, liquid nitrogen, liquid helium, etc. In some embodiments, the temperature regulation device 2428 may be, for example, a dilution refrigerator, a helium-3 refrigerator, or a liquid helium refrigerator. In some embodiments, the temperature regulation device 2428 or any portions thereof (e.g., one or more of the individual cooling devices) may be connected to the computing device 2400 in close proximity (e.g., less than about 1 meter) or may be provided in a separate enclosure where a dedicated heat exchanger (e.g., a compressor, a heating, ventilation, and air conditioning (HVAC) system, liquid helium, liquid nitrogen, etc.) may reside.

By maintaining the target temperatures, the energy consumption of the computing device 2400 (or components thereof) can be reduced, while the computing efficiency may be improved. For example, when the computing device 2400 (or components thereof) operates at lower temperatures, energy dissipation (e.g., heat dissipation) may be reduced. Further, energy consumed by semiconductor components (e.g., energy needed for switching transistors of any of the components of the computing device 2400) can also be reduced. Various semiconductor materials may have lower resistivity and/or higher mobility at lower temperatures. That way, the electrical current per unit supply voltage may be increased by lowering temperatures. Conversely, for the same current that would be needed, the supply voltage may be lowered by lowering temperatures. As energy corelates to the supply voltage, the energy consumption of the semiconductor components may lower too. In some implementations, the energy savings due to reducing heat dissipation and reducing energy consumed by semiconductor components of the computing device or components thereof may outweigh (sometimes significantly outweigh) the costs associated with energy needed for cooling.

The computing device 2400 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 2400 may be any other electronic device that processes data.

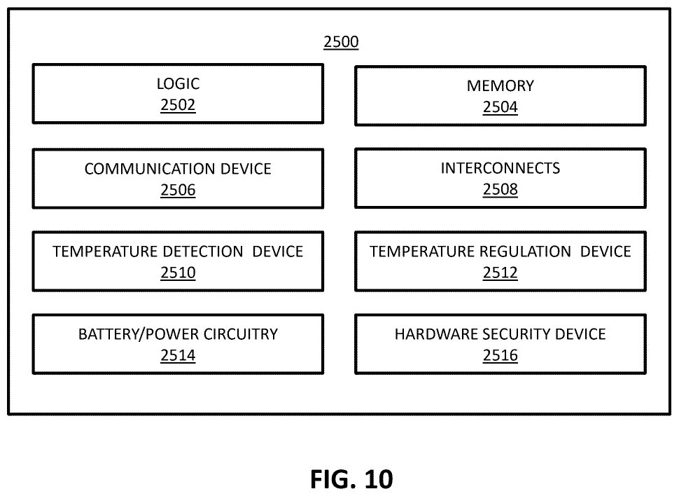

FIG. 10 is a block diagram of an example processing device 2500 that may include one or more IC devices with one or more negative differential impedance memory cells in accordance with any of the embodiments disclosed herein. For example, any suitable ones of the components of the processing device 2500 may include a die (e.g., the die 2102 of FIG. 6) having one or more negative differential impedance memory cells as described herein. Any one or more of the components of the processing device 2500 may include, or be included in, an IC device 1400 (FIG. 8). Any one or more of the components of the processing device 2500 may include, or be included in, an IC package 2200 of FIG. 7 or an IC device 2300 of FIG. 8. Any one or more of the components of the processing device 2500 may include, or be included in, a computing device 2400 of FIG. 9; for example, the processing device 2500 may be the processing device 2402 of the computing device 2400.

A number of components are illustrated in FIG. 10 as included in the processing device 2500, but any one or more of these components may be omitted or duplicated, as suitable for the application. In some embodiments, some or all of the components included in the processing device 2500 may be attached to one or more motherboards. In some embodiments, some or all of these components are fabricated on a single SoC die or coupled to a single support structure, e.g., to a single carrier substrate.

Additionally, in various embodiments, the processing device 2500 may not include one or more of the components illustrated in FIG. 10, but the processing device 2500 may include interface circuitry for coupling to the one or more components. For example, the processing device 2500 may not include a memory 2504, but may include display device interface circuitry (e.g., a connector and driver circuitry) to which a memory 2504 may be coupled.

The processing device 2500 may include logic circuitry 2502 (e.g., one or more circuits configured to implement logic/compute functionality). Examples of such circuits include ICs implementing one or more of input/output (I/O) functions, arithmetic operations, pipelining of data, etc.

In some embodiments, the logic circuitry 2502 may include one or more circuits responsible for read/write operations with respect to the data stored in the memory 2504. To that end, the logic circuitry 2502 may include one or more I/O ICs configured to control access to data stored in the memory 2504.

In some embodiments, the logic circuitry 2502 may include one or more high-performance compute dies, configured to perform various operations with respect to data stored in the memory 2504 (e.g., arithmetic and logic operations, pipelining of data from one or more memory dies of the memory 2504, and possibly also data from external devices/chips). In some embodiments, the logic circuitry 2502 may be configured to only control I/O access to data but not perform any operations on the data. In some embodiments, the logic circuitry 2502 may implement ICs configured to implement I/O control of data stored in the memory 2504, assemble data from the memory 2504 for transport (e.g., transport over a central bus) to devices/chips that are either internal or external to the processing device 2500, etc. In some embodiments, the logic circuitry 2502 may not be configured to perform any operations on the data besides I/O and assembling for transport to the memory 2504.

The processing device 2500 may include a memory 2504, which may include one or more ICs configure to implement memory circuitry (e.g., ICs implementing one or more of memory devices, memory arrays, control logic configured to control the memory devices and arrays, etc.). In some embodiments, the memory 2504 may be implemented substantially as described above with reference to the memory 1604 (FIG. 9). In some embodiments, the memory 2504 may be a designated device configured to provide storage functionality for the components of the processing device 2500 (i.e., local), while the memory 1604 may be configured to provide system-level storage functionality for the entire computing device 1600 (i.e., global). In some embodiments, the memory 2504 may include memory that shares a die with the logic circuitry 2502.

In some embodiments, the memory 2504 may include a flat memory (also sometimes referred to as a “flat hierarchy memory” or a “linear memory”) and, therefore, may also be referred to as a “basin memory.” As known in the art, a flat memory or a linear memory refers to a memory addressing paradigm in which memory may appear to the program as a single contiguous address space, where a processor can directly and linearly address all of the available memory locations without having to resort to memory segmentation or paging schemes. Thus, the memory implemented in the memory 2504 may be a memory that is not divided into hierarchical layer or levels in terms of access of its data.

In some embodiments, the memory 2504 may include a hierarchical memory. In this context, hierarchical memory refers to the concept of computer architecture where computer storage is separated into a hierarchy based on features of memory such as response time, complexity, capacity, performance, and controlling technology. Designing for high performance may require considering the restrictions of the memory hierarchy, i.e., the size and capabilities of each component. With hierarchical memory, each of the various memory components can be viewed as part of a hierarchy of memories (m₁, m₂, . . . , mₙ) in which each member mᵢ is typically smaller and faster than the next highest member min of the hierarchy. To limit waiting by higher levels, a lower level of a hierarchical memory structure may respond by filling a buffer and then signaling for activating the transfer. For example, in some embodiments, the hierarchical memory implemented in the memory 2504 may be separated into four major storage levels: 1) internal storage (e.g., processor registers and cache), 2) main memory (e.g., the system RAM and controller cards), and 3) on-line mass storage (e.g., secondary storage), and 4) off-line bulk storage (e.g., tertiary, and off-line storage). However, as the number of levels in the memory hierarchy and the performance at each level has increased over time and is likely to continue to increase in the future, this example hierarchical division provides only one non-limiting example of how the memory 2504 may be arranged.

The processing device 2500 may include a communication device 2506, which may be implemented substantially as described above with reference to the communication chip 1606 (FIG. 9). In some embodiments, the communication device 2506 may be a designated device configured to provide communication functionality for the components of the processing device 2500 (i.e., local), while the communication chip 1606 may be configured to provide system-level communication functionality for the entire computing device 1600 (i.e., global).

The processing device 2500 may include interconnects 2508, which may include any element or device that includes an electrically conductive material for providing electrical connectivity to one or more components of, or associated with, a processing device 2500 or/and between various such components. Examples of the interconnects 2508 include conductive lines/wires (also sometimes referred to as “lines” or “metal lines” or “trenches”) and conductive vias (also sometimes referred to as “vias” or “metal vias”), metallization stacks, redistribution layers, metal-insulator-metal (MIM) structures, etc.

The processing device 2500 may include a temperature detection device 2510 which may be implemented substantially as described above with reference to the temperature detection device 2426 of FIG. 9 but configured to determine temperatures on a more local scale, i.e., of the processing device 2500 of components thereof. In some embodiments, the temperature detection device 2510 may be a designated device configured to provide temperature detection functionality for the components of the processing device 2500 (i.e., local), while the temperature detection device 2426 may be configured to provide system-level temperature detection functionality for the entire computing device 2400 (i.e., global).

The processing device 2500 may include a temperature regulation device 2512 which may be implemented substantially as described above with reference to the temperature regulation device 2428 of FIG. 9 but configured to regulate temperatures on a more local scale, i.e., of the processing device 2500 of components thereof. In some embodiments, the temperature regulation device 2512 may be a designated device configured to provide temperature regulation functionality for the components of the processing device 2500 (i.e., local), while the temperature regulation device 2428 may be configured to provide system-level temperature regulation functionality for the entire computing device 2400 (i.e., global).

The processing device 2500 may include a battery/power circuitry 2514 which may be implemented substantially as described above with reference to the battery/power circuitry 2410 of FIG. 9. In some embodiments, the battery/power circuitry 2514 may be a designated device configured to provide battery/power functionality for the components of the processing device 2500 (i.e., local), while the battery/power circuitry 2410 may be configured to provide system-level battery/power functionality for the entire computing device 2400 (i.e., global).

The processing device 2500 may include a hardware security device 2516 which may be implemented substantially as described above with reference to the security interface device 2424 of FIG. 9. In some embodiments, the hardware security device 2516 may be a physical computing device configured to safeguard and manage digital keys, perform encryption and decryption functions for digital signatures, authentication, and other cryptographic functions. In some embodiments, the hardware security device 2516 may include one or more secure cryptoprocessors chips.

The above description of illustrated implementations of the disclosure, including what is described in the Abstract, is not intended to be exhaustive or to limit the disclosure to the precise forms disclosed. Unless specified otherwise, in various embodiments, features described with respect to one of the drawings may be combined with those described with respect to other drawings.

### Select Examples

The following paragraphs provide various examples of the embodiments disclosed herein.

Example 1 provides a device including a first semiconductor region extending in a first direction along across at least a portion of a device region; a second semiconductor region coupled to the first semiconductor region, the second semiconductor region extending in a second direction perpendicular to the first direction; a first conductive structure coupled to a first portion of the second semiconductor region and over the first semiconductor region; a second conductive structure coupled to a second portion of the second semiconductor region, the second conductive structure over the first conductive structure; and a third conductive structure coupled to a third portion of the second semiconductor region, the third conductive structure over the second conductive structure.

Example 2 provides the device of example 1, where the first semiconductor region has a first carrier type, and the second semiconductor region has a second carrier type that is opposite the first carrier type.

Example 3 provides the device of example 2, further including a third semiconductor region over the second semiconductor region, the third semiconductor region having a higher concentration of a dopant than the second semiconductor region.

Example 4 provides the device of any preceding example, where the first semiconductor region has an upper surface, and the second direction is perpendicular to the upper surface of the first semiconductor region.

Example 5 provides the device of example 4, where the second semiconductor region is a first pillar, the device further including a second pillar coupled to the first semiconductor region, the second pillar separated from the first pillar, and the second pillar extending in the second direction in parallel to the first pillar.

Example 6 provides the device of example 5, where the first conductive structure, second conductive structure, and third conductive structure are coupled to the second pillar.

Example 7 provides the device of any preceding example, where the first conductive structure, second conductive structure, and third conductive structure are physically separated from one another.

Example 8 provides the device of any preceding example, further including a first dielectric layer between the first conductive structure and the second conductive structure; and a second dielectric layer between the second conductive structure and the third conductive structure.

Example 9 provides the device of any preceding example, where the first conductive structure, second conductive structure, and third conductive structure are electrically independent from each other.

Example 10 provides the device of any preceding example, further including a first via coupled to the first conductive structure; a second via coupled to the second conductive structure; and a third via coupled to the third conductive structure.

Example 11 provides the device of any preceding example, further including a layer of a dielectric material between the second semiconductor region and the first, second, and third conductive structures.

Example 12 provides an assembly including a packaging component; and a device coupled to the packaging component, the device including a semiconductor pillar having a first end, a second end, and a sidewall between the first end and the second end; a dielectric layer along the sidewall of the semiconductor pillar; and a stack of conductive structures surrounding the dielectric layer, the stack including a first conductive structure proximate to the first end of the semiconductor pillar; a second conductive structure proximate to the second end of the semiconductor pillar; and a third conductive structure between the first conductive structure and the second conductive structure.

Example 13 provides the assembly of example 12, where the device includes a memory region, the memory region including the semiconductor pillar, dielectric layer, and stack of conductive structures.

Example 14 provides the assembly of example 12, where, in a cross-section through the semiconductor pillar and the stack of conductive structures, a first portion of the dielectric layer is between a first side of the semiconductor pillar and the stack of conductive structures, and a second portion of the dielectric layer is between a second side of the semiconductor pillar and the stack of conductive structures.

Example 15 provides a memory device including a first memory cell including a first pillar, the first pillar coupled to a plurality of gates arranged at different positions along the first pillar; and a second memory cell including a second pillar, the second pillar coupled to the plurality of gates.

Example 16 provides the memory device of example 15, where the plurality of gates includes a first gate, a second gate, and a third gate, and the second gate is between the first gate and the third gate.

Example 17 provides the memory device of example 16, where the first gate and the third gate are coupled to a word line, and the second gate is independently controlled.

Example 18 provides the memory device of any of examples 15-17, where a first end of the first pillar is coupled to a first bitline, and a second end of the first pillar is coupled to a second bitline.

Example 19 provides the memory device of example 18, where a first end of the second pillar is further coupled to the first bitline.

Example 20 provides the memory device of any of examples 15-19, where a plurality of pillars includes the first pillar and the second pillar, and the plurality of pillars are arranged in hexagonal pattern.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. A device comprising:
a first semiconductor region extending in a first direction along across at least a portion of a device region;
a second semiconductor region coupled to the first semiconductor region, the second semiconductor region extending in a second direction perpendicular to the first direction;
a first conductive structure coupled to a first portion of the second semiconductor region and over the first semiconductor region;
a second conductive structure coupled to a second portion of the second semiconductor region, the second conductive structure over the first conductive structure; and
a third conductive structure coupled to a third portion of the second semiconductor region, the third conductive structure over the second conductive structure.

2. The device of claim 1, wherein the first semiconductor region has a first carrier type, and the second semiconductor region has a second carrier type that is opposite the first carrier type.

3. The device of claim 2, further comprising a third semiconductor region over the second semiconductor region, the third semiconductor region having a higher concentration of a dopant than the second semiconductor region.

4. The device of claim 1, wherein the first semiconductor region has an upper surface, and the second direction is perpendicular to the upper surface of the first semiconductor region.

5. The device of claim 4, wherein the second semiconductor region is a first pillar, the device further comprising a second pillar coupled to the first semiconductor region, the second pillar separated from the first pillar, and the second pillar extending in the second direction in parallel to the first pillar.

6. The device of claim 5, wherein the first conductive structure, second conductive structure, and third conductive structure are coupled to the second pillar.

7. The device of claim 1, wherein the first conductive structure, second conductive structure, and third conductive structure are physically separated from one another.

8. The device of claim 1, further comprising:
a first dielectric layer between the first conductive structure and the second conductive structure; and
a second dielectric layer between the second conductive structure and the third conductive structure.

9. The device of claim 1, wherein the first conductive structure, second conductive structure, and third conductive structure are electrically independent from each other.

10. The device of claim 1, further comprising:
a first via coupled to the first conductive structure;
a second via coupled to the second conductive structure; and
a third via coupled to the third conductive structure.

11. The device of claim 1, further comprising a layer of a dielectric material between the second semiconductor region and the first, second, and third conductive structures.

12. An assembly comprising:
a packaging component; and
a device coupled to the packaging component, the device comprising:
a semiconductor pillar having a first end, a second end, and a sidewall between the first end and the second end;
a dielectric layer along the sidewall of the semiconductor pillar; and
a stack of conductive structures surrounding the dielectric layer, the stack comprising:
a first conductive structure proximate to the first end of the semiconductor pillar;
a second conductive structure proximate to the second end of the semiconductor pillar; and
a third conductive structure between the first conductive structure and the second conductive structure.

13. The assembly of claim 12, wherein the device comprises a memory region, the memory region including the semiconductor pillar, dielectric layer, and stack of conductive structures.

14. The assembly of claim 12, wherein, in a cross-section through the semiconductor pillar and the stack of conductive structures, a first portion of the dielectric layer is between a first side of the semiconductor pillar and the stack of conductive structures, and a second portion of the dielectric layer is between a second side of the semiconductor pillar and the stack of conductive structures.

15. A memory device comprising:
a first memory cell comprising a first pillar, the first pillar coupled to a plurality of gates arranged at different positions along the first pillar; and
a second memory cell comprising a second pillar, the second pillar coupled to the plurality of gates.

16. The memory device of claim 15, wherein the plurality of gates comprises a first gate, a second gate, and a third gate, and the second gate is between the first gate and the third gate.

17. The memory device of claim 16, wherein the first gate and the third gate are coupled to a word line, and the second gate is independently controlled.

18. The memory device of claim 15, wherein a first end of the first pillar is coupled to a first bitline, and a second end of the first pillar is coupled to a second bitline.

19. The memory device of claim 18, wherein a first end of the second pillar is further coupled to the first bitline.

20. The memory device of claim 15, wherein a plurality of pillars includes the first pillar and the second pillar, and the plurality of pillars are arranged in hexagonal pattern.
